(19) United States
(12) Patent Application Publication
(10) Pub. No.: US 2025/0293119 A1
(43) Pub. Date: Sep. 18, 2025

(54) COOLER AND SEMICONDUCTOR APPARATUS THEREWITH

(71) Applicant: FUJI ELECTRIC CO., LTD., Kawasaki-shi (JP)

(72) Inventor: Akira KAMIYA, Tokyo (JP)

(73) Assignee: FUJI ELECTRIC CO., LTD., Kawasaki-shi (JP)

(21) Appl. No.: 19/222,350

(22) Filed: May 29, 2025

Related U.S. Application Data
(63) Continuation of application No. PCT/JP2024/021678, filed on Jun. 14, 2024.

(30) Foreign Application Priority Data
Jun. 20, 2023 (KR) 2023-100653

(51) Int. Cl. H01L 23/473; H01L 25/07

(52) U.S. Cl. CPC H01L 23/473; H01L 25/072

(57) ABSTRACT

A cooler includes a heat dissipation substrate including a first main face on which one or more semiconductor devices are mounted and a second main face with a fin part; a case body that is in close contact with the second main face and configured to accommodate the fin part; and a structure. The case body includes a first wall portion, a second wall portion facing the first wall portion, an inlet port for introducing coolant into an interior of the case body, and a discharge port for discharging the coolant from the interior of the case body, the discharge port being positioned relative to the inlet port in a direction of a main line extending from the first wall portion to the second wall portion. The structure is configured to intake the coolant flowing in from the inlet port into the interior, and directs the coolant in a guide direction intersecting the main line, to allow the coolant to flow out from a position that corresponds to the fin part.

### CROSS REFERENCE TO RELATED APPLICATION

This application is a Continuation Application of PCT Application No. PCT/JP2024/021678, filed Jun. 14, 2024, and is based on and claims priority from Japanese Patent Application No. 2023-100653, filed Jun. 20, 2023, the entire contents of which are incorporated herein by reference.

### BACKGROUND

### Technical Field

The present disclosure relates to a cooler and to a semiconductor apparatus therewith.

### Description of Related Art

Conventionally, there is known a semiconductor apparatus including a semiconductor module and a cooler for cooling the semiconductor module. In addition, a liquid-cooled cooler in which a liquid is used as a coolant is known. International Publication No. 2014/069174 and Japanese Patent Application Laid-Open Publication No. 2020-145245 disclose a cooling structure including a heat dissipation substrate joined to a semiconductor module, and a cooling case having a box shape with one surface open and the open surface attached to the heat dissipation substrate. In this cooling structure, a heat dissipation fin is provided on the heat dissipation substrate, and the cooling case is attached to the heat dissipation substrate so as to house the fin therein. Furthermore, the cooling case is provided with an inlet port and a discharge port, and the fin is cooled by the coolant by allowing it to flow from the inlet port to the discharge port.

International Publication No. 2014/069174 and Japanese Patent Application Laid-Open Publication No. 2020-145245 also show a structure in which a convex body is provided inside a cooling case, and the coolant flowing in from the inlet port is diffused by the convex body to improve cooling efficiency.

However, in the conventional cooling structure, diffusion of the coolant in a direction intersecting a straight line connecting the inlet port and the discharge port is not sufficient. Therefore, the cooling effect is weaker at a position away from the straight line, and as a result, the temperature of the semiconductor device increases. Therefore, there is a problem in that temperature differences occur among different semiconductor devices.

### SUMMARY

An object of the present disclosure is to provide a cooler and a semiconductor apparatus capable of suppressing temperature differences depending on the positions of one or more semiconductor devices and reducing the temperature at the position with the highest temperature.

A cooler according to one aspect of the present disclosure includes a heat dissipation substrate including a first main face on which one or more semiconductor devices are mounted and a second main face with a fin part; a case body that is in close contact with the second main face and configured to accommodate the fin part; and a structure. The case body includes: a first wall portion, a second wall portion facing the first wall portion, an inlet port for introducing coolant into an interior of the case body, and a discharge port for discharging the coolant from the interior of the case body, the discharge port being positioned relative to the inlet port in a direction of a main line extending from the first wall portion to the second wall portion. The structure is configured to intake the coolant flowing in from the inlet port into the interior, and directs the coolant in a guide direction intersecting the main line, to allow the coolant to flow out from a position that corresponds to the fin part.

A semiconductor apparatus according to one aspect of the present disclosure includes: one or more semiconductor devices; a cooler for cooling the one or more semiconductor devices, in which the cooler includes: a heat dissipation substrate including a first main face on which the one or more semiconductor devices are mounted and a second main face with a fin part; a case body that is in close contact with the second main face and configured to accommodate the fin part; and a structure. The case body includes: a first wall portion, a second wall portion facing the first wall portion, an inlet port for introducing coolant into an interior of the case body, and a discharge port configured to discharge the coolant from the interior of the case body, the discharge port being positioned relative to the inlet port in a direction of a main line extending from the first wall portion to the second wall portion. The structure is configured to intake the coolant flowing in from the inlet port into the interior, and directs the coolant in a guide direction intersecting the main line, to cause the coolant to flow out from a position that corresponds to the fin part.

### BRIEF DESCRIPTION OF DRAWINGS

FIG. 1 is a perspective view illustrating an example of a configuration of a semiconductor apparatus according to an embodiment of the present disclosure.

FIG. 2 is a plan view illustrating an example of a configuration of the semiconductor apparatus.

FIG. 3 is a front view of the semiconductor apparatus as viewed from a side at which an inlet portion is provided.

FIG. 4 is a cross-sectional view of the semiconductor apparatus in FIG. 2, taken along line IV-IV.

FIG. 5 is a view of the semiconductor apparatus in FIG. 2, viewed from line V-V.

FIG. 6 is a perspective view of a case body viewed from above.

FIG. 7 is a plan view of the case body viewed from above.

FIG. 8 is a cross-sectional view of the case body in FIG. 6, taken along line VIII-VIII.

FIG. 9 is a view of the case body in FIG. 6, as viewed from line IX-IX.

FIG. 10 is a schematic diagram showing the flow of a coolant, as viewed from above the case body.

FIG. 11 is a diagram schematically showing the flow of the coolant in a cross section of the case body.

FIG. 12 is a diagram showing a simulation result of the temperature of each of the six semiconductor devices mounted on the cooler.

FIG. 13 is a diagram showing a simulation result of pressure loss in the cooler.

FIG. 14 is a diagram showing an example of a configuration of the case body according to a first modification of the present disclosure.

FIG. 15 is an exploded perspective view showing an example of a configuration of a case body according to a second modification of the present disclosure.

FIG. 16 is a cross-sectional view of a semiconductor apparatus according to a seventh modification of the present disclosure.

FIG. 17 is a cross-sectional view of a semiconductor apparatus according to an eighth modification of the present disclosure.

FIG. 18 is a plan view of a semiconductor apparatus according to a ninth modification of the present disclosure.

FIG. 19 is a circuit diagram of a power converter (inverter circuit).

FIG. 20 is a plan view of a semiconductor apparatus according to another form of the ninth modification.

FIG. 21 is a plan view of a semiconductor apparatus according to another form of the ninth modification.

FIG. 22 is a plan view of a semiconductor apparatus according to a tenth modification.

FIG. 23 is a cross-sectional view in FIG. 22, taken along line XXIII-XXIII.

FIG. 24 is a plan view of a semiconductor apparatus according to an eleventh modification.

FIG. 25 is a plan view of a semiconductor apparatus according to a twelfth modification.

FIG. 26 is a plan view of a semiconductor apparatus according to another form of the twelfth modification.

FIG. 27 is a plan view of a semiconductor apparatus according to another form of the twelfth modification.

### DESCRIPTION OF EMBODIMENT

In the following, a preferred embodiment of the present disclosure will be described with reference to the drawings. In the drawings, the dimensions and scales of the respective parts may be appropriately different from those of the actual parts, and may include portions schematically illustrated to facilitate understanding. In addition, in the following description, the scope of the present disclosure is not limited to the forms described in the following description unless otherwise stated to limit the present disclosure. The scope of the present disclosure includes equivalent ranges of such forms.

### 1. Embodiment

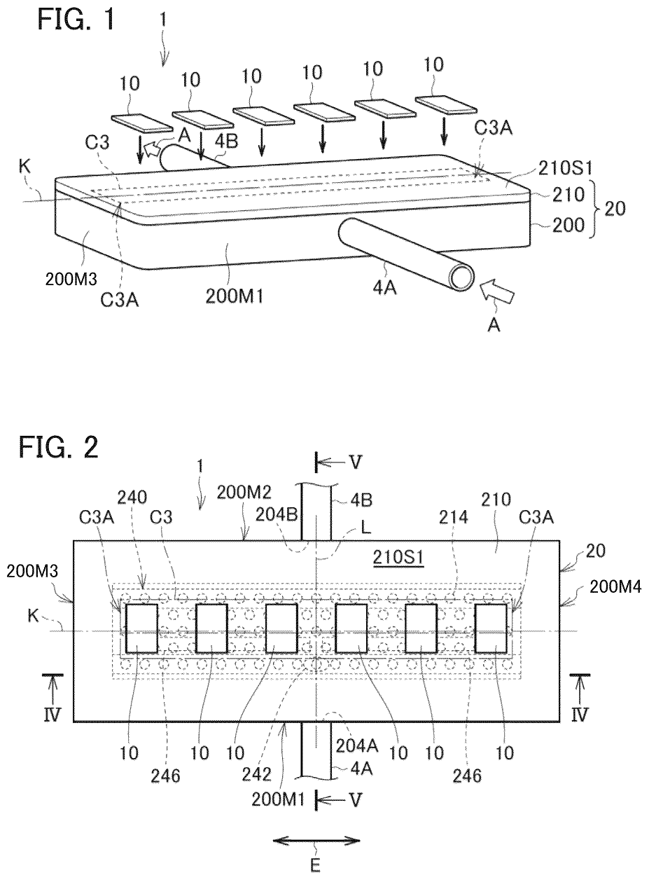

FIG. 1 is a perspective view illustrating an example of a configuration of a semiconductor apparatus 1 according to an embodiment of the present disclosure, and FIG. 2 is a plan view illustrating an example of a configuration of the semiconductor apparatus 1. FIG. 1 is an assembled view showing a state in which the semiconductor device 10 is mounted on a cooler 20. FIG. 2 is also a transparent view of an internal structure of the cooler 20.

The semiconductor apparatus 1 includes one or more semiconductor devices 10 and a cooler 20 on which the one or more semiconductor devices 10 are mounted. A semiconductor device 10 is a switching device such as an IGBT (Insulated Gate Bipolar Transistor) and a MOSFET (Metal Oxide Semiconductor Field Effect Transistor). At least one of a plurality of semiconductor devices 10 may be a wide bandgap semiconductor device. The wide bandgap semiconductor device is a semiconductor device having a bandgap greater than that of a silicon semiconductor device, and is a semiconductor device including, for example, SiC, GaN, diamond, gallium nitride-based material, gallium oxide-based material, AlN, AlGaN, or ZnO. Wide bandgap semiconductor devices can improve the switching speed than silicon semiconductor devices. The one or more semiconductor devices 10 may be joined to a conductive pattern provided on an insulating substrate, and may be mounted on the cooler 20 via the conductive pattern and the insulating substrate.

The number of the semiconductor devices 10 included in the semiconductor apparatus 1 of the present embodiment is two or more, and as shown in FIG. 2, the semiconductor devices 10 are mounted on the cooler 20, being arranged in a row at intervals. The distance between the semiconductor devices 10 may or may not be constant.

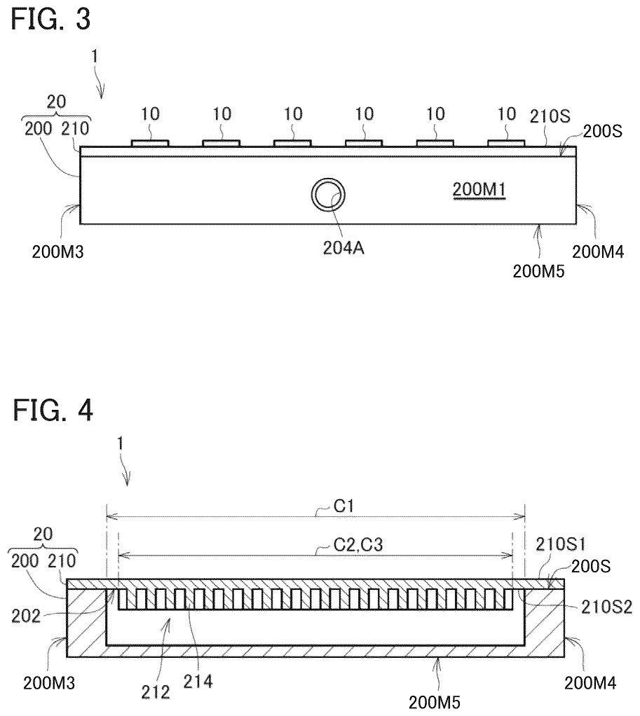

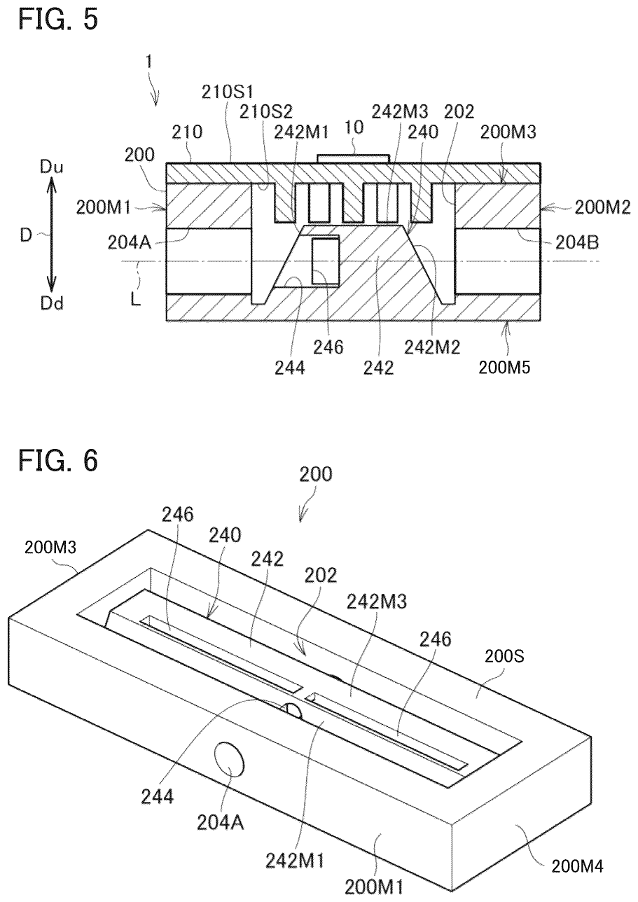

FIG. 3 is a view of the semiconductor apparatus 1, viewed from the side where an inlet port 204A is provided. FIG. 4 is a cross-sectional view of the semiconductor apparatus 1 in FIG. 2, taken along line IV-IV. FIG. 5 is a view of the semiconductor apparatus 1 in FIG. 2, as viewed from line V-V. In FIG. 3, an inlet tube 4A is not shown, and in FIG. 5, the inlet tube 4A and an outlet tube 4B are not shown.

The cooler 20 is a device that cools the semiconductor devices 10 by a liquid coolant A. That is, the semiconductor devices 10 are objects to be cooled by the cooler 20. The type of the liquid used for the coolant A is not limited.

As shown in FIG. 4, the cooler 20 of the present embodiment includes a case body 200 provided with an opening 202, and a heat dissipation substrate 210 that closes the opening 202 of the case body 200. The semiconductor devices 10 are mounted on a first main face 210S1 of the heat dissipation substrate 210. The case body 200 is also referred to as a water jacket.

The heat dissipation substrate 210 is a plate-shaped member. The heat dissipation substrate 210 includes the first main face 210S1 and a second main face 210S2. The first main face 210S1 and the second main face 210S2 are main faces facing away from each other. The heat dissipation substrate 210 is primarily composed of a highly thermally conductive material. Examples of such materials include metals, such as copper and aluminum, or alloys. On the first main face 210S1 of the heat dissipation substrate 210, the semiconductor device 10 is joined using a joining material primarily including a highly thermally conductive material.

As shown in FIG. 4, of the second main face 210S2, which is the back side of the first main face 210S1, of the heat dissipation substrate 210, a fin part 212 is provided in an area C1 that faces the opening 202 of the case body 200. The fin part 212 includes a plurality of fins 214 provided upright on the second main face 210S2. The plurality of fins 214 is accommodated within the case body 200, having been inserted through the opening 202 into the interior of the case body 200.

The shape of each of the plurality of fins 214 is freely selected, and may be, for example, a pillar shape or a plate shape. Not all of the fins 214 need be of the same shape. Furthermore, the fin part 212 may be integrally molded with the heat dissipation substrate 210 as a single unit or may be separate from the heat dissipation substrate 210. In the present embodiment, as shown in FIGS. 2 and 4, a fin 214 has a pillar shape. Furthermore, the arrangement of each of the plurality of fins 214 is also freely selected, and for example, the plurality of fins 214 may be arranged in a grid pattern or may be arranged in a zigzag pattern in plan view.

As shown in FIG. 4, the case body 200 is a so-called box-shaped member having a hollow three-dimensional shape. A material having a high thermal conductivity is used as a main material of the case body 200. Typical examples of such materials include metals, such as copper and aluminum, or alloys thereof.

The case body 200 includes a first wall portion 200M1, a second wall portion 200M2, a third wall portion 200M3, a fourth wall portion 200M4, and a bottom surface portion 200M5. The first wall portion 200M1, the second wall portion 200M2, the third wall portion 200M3, and the fourth wall portion 200M4 are connected in a rectangular frame shape in plan view to form side walls of the case body 200.

As shown in FIG. 1, the first wall portion 200M1 is a plate-shaped portion that constitutes a side surface of the case body 200. The first wall portion 200M1 is provided with one inlet port 204A into which the coolant A is introduced.

As shown in FIGS. 2 and 5, the second wall portion 200M2 is a plate-shaped portion constituting a side surface of the case body 200. The second wall portion 200M2 faces the first wall portion 200M1. The second wall portion 200M2 is provided with one discharge port 204B for discharging the coolant A from the inside.

In the present embodiment, the inlet port 204A and the discharge port 204B are provided at locations opposite to each other. That is, the discharge port 204B is positioned on the extension line that is in a direction in which the inlet port 204A penetrates the first wall portion 200M1. The direction of the extension line corresponds to a direction of the main line L, described later.

The third wall portion 200M3 and the fourth wall portion 200M4 are surfaces facing each other, and each of the surfaces is a plate-shaped portion constituting a side surface of the case body 200. As shown in FIG. 2, the third wall portion 200M3 and the fourth wall portion 200M4 intersect the first wall portion 200M1 and the second wall portion 200M2.

It is to be noted that each of the first wall portion 200M1 to the fourth wall portion 200M4 may be a flat surface, or may include a curved surface, an uneven surface, and the like in part or overall. Furthermore, each of the first wall portion 200M1 to the fourth wall portion 200M4 may include two or more flat surfaces. In a case in which all of the first wall portion 200M1 to the fourth wall portion 200M4 are flat surfaces, the case body 200 has a rectangular parallelepiped or a cubic shape.

The bottom surface portion 200M5 is a plate-shaped portion constituting the bottom surface of the case body 200. The first wall portion 200M1, the second wall portion 200M2, the third wall portion 200M3, and the fourth wall portion 200M4 protrude upward from the bottom surface portion 200M5.

As illustrated in FIG. 4, the sealing surface 200S comprises a top surface of the case body 200. Specifically, the top surface of the frame-shaped part composed of the first wall part 200M1, the second wall part 200M2, the third wall part 200M3, and the fourth wall part 200M4 comprises the sealing surface 200S. Accordingly, the sealing surface 200S is a plane substantially parallel to the bottom surface portion 200M5.

The above-described opening 202 is provided in the sealing surface 200S. The sealing surface 200S is brought into close contact with the second main face 210S2 of the heat dissipation substrate 210 by using a fastener such as a screw. In addition to the fastener, appropriate joining means such as adhesives or welding may be used. It is to be noted that the shape of the opening 202 in plan view may be freely selected, and is typically rectangular. The opening area of the opening 202 may also be freely selected.

In the following explanation, as illustrated in FIG. 5, the normal direction of the sealing surface 200S as the top surface and the bottom surface portion 200M5 are defined as the “up-and-down direction D”. In the up-and-down direction D, a direction from the bottom surface portion 200M5 toward the sealing surface 200S is defined as an “upward direction Du”, and a direction opposed to the “upward direction Du” is defined as a “downward direction Dd”.

As shown in FIG. 1, the inlet tube 4A is connected to the inlet port 204A, and the outlet tube 4B is connected to the discharge port 204B. At least one of the inlet tube 4A and the outlet tube 4B is connected to a pump that discharges or draws in the coolant A. By the operation of the pump, the coolant A is introduced into the interior of the case body 200 through the inlet tube 4A, flows through the interior of the case body 200, and is discharged from the interior of the case body 200 through the outlet tube 4B. It is to be noted that the pump is not shown. In a process in which the coolant A flows inside the case body 200, the amount of heat generated by the semiconductor devices 10 is removed by heat exchange with the fin part 212, and consequently the semiconductor devices 10 are cooled.

In the present embodiment, as shown in FIG. 4, in the second main face 210S2 of the heat dissipation substrate 210, the fin part 212 is provided at least over the entire range of a device cooling area C2 of the semiconductor device. The device cooling area C2 is an area located on the back side of the device mounting area C3 in the first main face 210S1, that is, an area located directly below the device mounting area C3 in a cross-sectional view. The device mounting area C3 is an area in which the semiconductor devices 10 can be mounted. Since the fin part 212 is provided over substantially the entire range of the device cooling area C2, the amount of heat generated by the semiconductor devices 10 mounted on the device mounting area C3 is efficiently removed to the coolant A through the fin part 212 directly below.

As shown in FIG. 1, the planar shape of the device mounting area C3 in the present embodiment is a shape extending along a long axis K. In a case in which the plurality of semiconductor devices 10 is mounted on the heat dissipation substrate 210, the plurality of semiconductor devices 10 is mounted side by side along the long axis K of the device mounting area C3. In other words, the long axis K of the device mounting area C3 serves as an alignment direction of the plurality of semiconductor devices 10.

On the other hand, assuming that there is no structure inside the case body 200, as shown in FIG. 2, the coolant A flows along the main line L, which is a line linearly connecting the inlet port 204A and the discharge port 204B. The main line L is an imaginary straight line from the first wall portion 200M1 toward the second wall portion 200M2. The main line Lis also regarded to as a straight line parallel to the normal line of the first wall portion 200M1 or the second wall portion 200M2.

As shown in FIGS. 1 and 2, the main line L does not coincide with the long axis K of the device mounting area C3 and intersects the long axis K. In the present embodiment, an angle formed by the long axis K of the device mounting area C3 and the main line L intersecting each other is approximately 90 degrees.

Therefore, when the coolant A flows along the main line L, the flow rate of the coolant A flowing directly below an end portion C3A on the long axis K in the device mounting area C3 is less than that in the vicinity of the main line L, and the amount of heat dissipated is also less. Consequently, in the device mounting area C3, the cooling effect is weaker as the distance from the main line Lis greater, and the temperature of the semiconductor device 10 increases as a result. A temperature difference is thus generated between the semiconductor devices 10.

Therefore, to reduce the temperature difference among the semiconductor devices 10, in the cooler 20 according to the present embodiment, as shown in FIG. 5, a convex structure 240 is provided on the bottom surface portion 200M5 of the case body 200. The structure 240 intakes the coolant A flowing in from the inlet port 204A into the interior thereof, to allow the taken-in coolant A to flow out from a position corresponding to the fin part 212, while directing the coolant A in a guide direction E. As shown in FIG. 2, the guide direction E of the structure 240 is substantially parallel to the direction of the long axis K of the device mounting area C3.

When the coolant A is guided in the guide direction E, the flow rate of the coolant A flowing directly below the end portion C3A of the device mounting area C3 increases. As the flow rate of the coolant A increases, the dissipated heat amount also increases, and consequently, the temperature differences among the semiconductor devices 10 are reduced in the device mounting area C3. Specifically, the temperature is reduced of semiconductor devices 10 that becomes the highest temperature. Furthermore, since the coolant A is guided in the guide direction E through the interior of the structure 240, the coolant A can be reliably guided in the guide direction E as compared with a configuration in which the coolant A flowing along the surface of the structure 240 is controlled by, for example, the surface shape of the structure 240.

In the following, the structure 240 will be described in more detail.

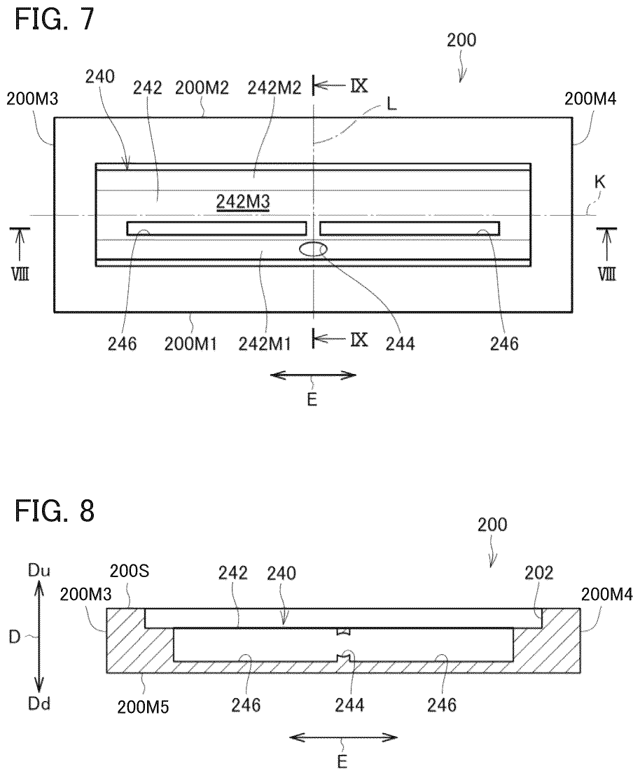

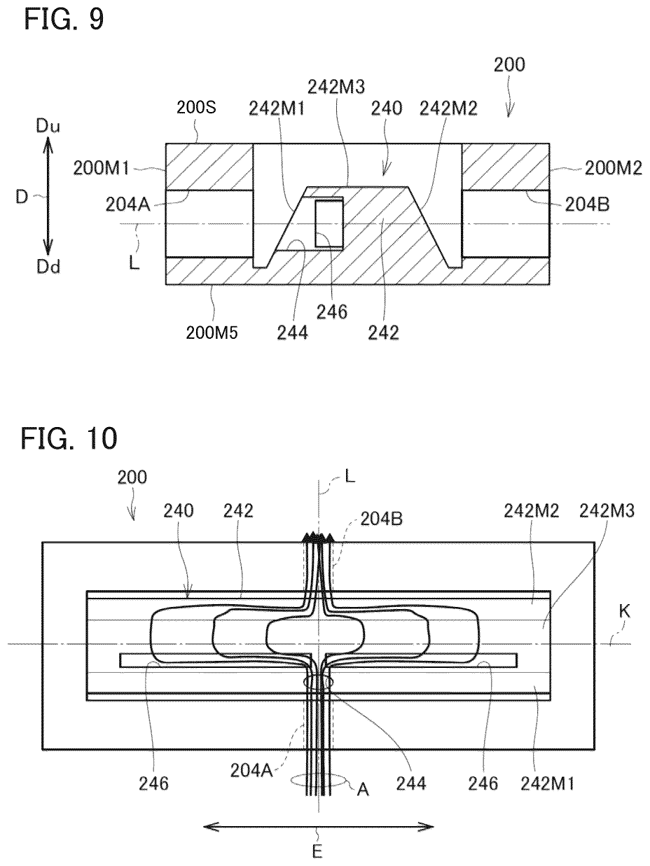

FIG. 6 is a perspective view of the case body 200 viewed from above, and FIG. 7 is a plan view of the case body 200 viewed from above. FIG. 8 is a cross-sectional view of the case body 200 in FIG. 6, taken along line VIII-VIII. FIG. 9 is a view of the case body 200 viewed from line IX-IX in FIG. 6.

As shown in FIGS. 6 and 7, the structure 240 includes a main body portion 242 having a substantially rod shape in plan view and extending between the third wall portion 200M3 and the fourth wall portion 200M4 in the direction of the long axis K of the device mounting area C3. Both ends of the main body portion 242 are connected to the inner surfaces of the third wall portion 200M3 and the fourth wall portion 200M4 without any gaps.

As the main material of the main body portion 242, a material having a high thermal conductivity is used as in the case body 200. As shown in FIG. 9, the cross-sectional shape of the main body portion 242 is a trapezoidal shape. Specifically, the main body portion 242 includes a first facing surface 242M1, a second facing surface 242M2, and an top surface 242M3.

The first facing surface 242M1 is a surface facing the inlet port 204A, and the second facing surface 242M2 is a surface facing the discharge port 204B. The top surface 242M3 is a surface connected to the first facing surface 242M1 and the second facing surface 242M2. Therefore, the top surface 242M3 faces the fin part 212 of the heat dissipation substrate 210.

The first facing surface 242M1 is inclined in a direction away from the inlet port 204A in the upward direction Du. In other words, the first facing surface 242M1 is an inclined surface inclined at an acute angle with respect to the bottom surface portion 200M5. The top surface 242M3 is a plane substantially parallel to the second main face 210S2 of the heat dissipation substrate 210, and is located in the vicinity of the fin part 212 in the up-and-down direction D while maintaining separation from the fin part 212. The second facing surface 242M2 is inclined in a direction closer to the discharge port 204B in the downward direction Dd. In other words, the second facing surface 242M2 is an inclined surface inclined at an acute angle with respect to the bottom surface portion 200M5. It is to be noted that the second facing surface 242M2 is not necessarily an inclined surface.

The first facing surface 242M1 of the present embodiment is provided with an intake hole 244 at a position facing the inlet port 204A. In other words, the intake hole 244 is provided on the main line L corresponding to the extension line that is in the penetrating direction of the inlet port 204A. The intake hole 244 is a lateral hole for taking in the coolant A flowing from the inlet port 204A into the structure 240. The intake hole 244 is a hole in the horizontal direction, with the depth direction of the hole being orthogonal to the up-and-down direction D.

On the other hand, as shown in FIG. 7, the top surface 242M3 is provided with a pair of outflow holes 246 sandwiching the main line L. Each of the pair of outflow holes 246 is a vertical hole for allowing the coolant A taken into the interior of the structure 240 to flow out from the top surface 242M3. The vertical hole is a hole having the depth direction corresponding to the up-and-down direction D. More specifically, the pair of outflow holes 246 communicate with the intake holes 244, respectively, as shown in FIGS. 8 and 9. As shown in FIGS. 7 and 8, each of the pair of outflow holes 246 is a hole having a shape extending in the guide direction E in plan view, and is an elongated hole. In the present embodiment, as described above, the guide direction E is substantially parallel to the long axis K of the device mounting area C3.

The structure 240 of the present embodiment is an integrally molded product with the case body 200. For example, die casting is used for integrally molding the structure 240 and the case body 200. The outflow hole 246, which is a vertical hole, is formed by a mold used for integral molding. Furthermore, the intake hole 244, which is a lateral hole, is formed by a tool which is inserted coaxially into the inlet port 204A after the inlet port 204A is formed by tapping or the like. According to this manufacturing method, in the manufacturing process of the case body 200, since the additional processing for providing the structure 240 is only the processing for forming the intake hole 244 in the structure 240, the increase in the processing cost is reduced.

Next, the flow of the coolant A will be described in detail.

FIG. 10 is a view schematically showing the flow of the coolant A, viewed from above the case body 200, and FIG. 11 is a view schematically showing the flow of the coolant A in the cross section of the case body 200. As shown in FIG. 11, inside the case body 200, the coolant A introduced from the inlet port 204A is taken in from the intake hole 244 of the structure 240. As described above, since the intake hole 244 is located on the extension line of the penetrating direction of the inlet port 204A, the coolant A is smoothly taken into the intake hole 244. The opening diameter of the intake hole 244 is appropriately set in accordance with a simulation result, etc., of a pressure loss, described later.

The coolant A taken in from the intake hole 244 flows toward each of the pair of outflow holes 246 communicating with the intake hole 244. Then, as shown in FIG. 10, the coolant A flows out from the top surface 242M3 while moving along the guide direction E in each of the pair of outflow holes 246. By the coolant A moving in the guide direction E, the coolant A spreads in the direction of the long axis K on the top surface 242M3, and the flow rate of the coolant A is secured even at a position away from the main line L in the direction of the long axis K of the device mounting area C3. The coolant A flowing out of the outflow hole 246 flows along the top surface 242M3 toward the discharge port 204B while removing the heat from the fin part 212, and is discharged from the discharge port 204B.

In the present embodiment, as shown in FIG. 2, of the device mounting area C3, the pair of outflow holes 246 is disposed directly below a region closer to the inlet port 204A than the discharge port 204B, that is, upstream of the flow of the coolant A in the top surface 242M3. According to the above-described configuration, in the top surface 242M3, the coolant A is allowed to flow in substantially the entire region directly below the semiconductor device 10. Therefore, the amount of heat generated by the semiconductor device 10 can be removed more efficiently, and the cooling performance can be improved.

As shown in FIG. 11, a part of the coolant A introduced from the inlet port 204A reaches the top surface 242M3 along the first facing surface 242M1 of the main body portion 242. In plan view, the flow rate of the coolant A is large in the vicinity of the main line L, and decreases as the distance from the main line L increases in the direction of the long axis K of the device mounting area C3, so that the cooling performance in the vicinity of the main line Lis relatively high.

On the other hand, since the pair of outflow holes 246 is provided, sandwiching the main line L, the flow rate of the coolant A flowing out from the respective outflow hole 246 is the smallest near the main line L, and in the direction of the long axis K of the device mounting area C3, the cooling performance near the main line Lis relatively low.

As a result, in the direction of the long axis K of the device mounting area C3, the cooling performance by the coolant A flowing along the first facing surface 242M1 is balanced with the cooling performance by the coolant A flowing out of each of the pair of outflow holes 246.

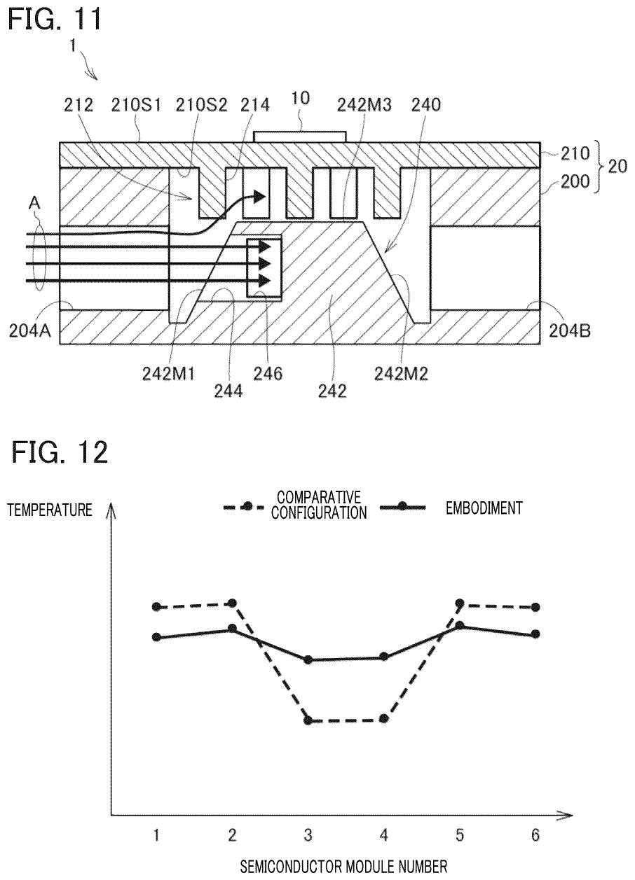

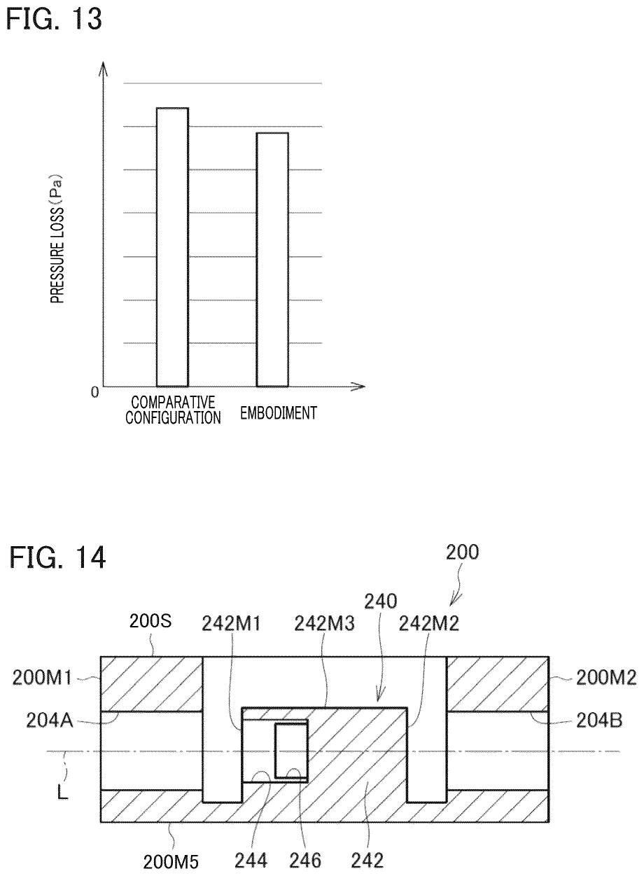

FIG. 12 is a diagram illustrating a simulation result of the temperature of each of the six semiconductor devices 10 mounted on the cooler 20, and FIG. 13 is a diagram illustrating a simulation result of the pressure loss in the cooler 20. In FIG. 13, the semiconductor device number indicates the order of the semiconductor devices 10 counted from one end of the row of the six semiconductor devices 10. The pressure drop of the coolant A in FIG. 13 is the difference between the pressure at the inlet port 204A and the pressure at the discharge port 204B. Furthermore, in FIGS. 12 and 13, a comparative configuration is that the intake hole 244 and the pair of outflow holes 246 are not provided in the structure 240 as a comparison to the configuration of the semiconductor apparatus 1 of the present embodiment.

As shown in FIG. 12, since the coolant A is guided by the structure 240 in the guide direction E, the temperature differences among the six semiconductor devices 10 in the device mounting area C3 are also smaller than those in the comparative configuration.

Furthermore, as shown in FIG. 13, inside the case body 200, a flow path is formed that passes through the interior of the structure 240 and reaches the top surface 242M3 of the structure 240, with the flow path comprising the intake hole 244 and the pair of outflow holes 246, it is evident that the pressure loss is reduced compared with the comparative configuration without such a flow path. By reducing the pressure loss, the stagnation of the coolant A in the cooler 20 is reduced, and thus, the cooling performance is enhanced.

As described above, the cooler 20 of the present embodiment includes a heat dissipation substrate 210 in which one or more semiconductor devices 10 are mounted on a first main face 210S1, and a case body 200 which is in close contact with a second main face 210S2 of the heat dissipation substrate 210 and that accommodates a fin part 212 provided on the second main face 210S2. The case body 200 includes a first wall portion 200M1 provided with an inlet port 204A for introducing a coolant A into the interior of the case body 200, and a second wall portion 200M2 facing the first wall portion 200M1 and provided with a discharge port 204B for discharging the coolant A from the interior of the case body 200. A structure 240 is provided that intakes the coolant A flowing from the inlet port 204A into the interior, directs the coolant A in a guide direction E intersecting a main line L linearly connecting the inlet port 204A and the discharge port 204B, to allow the coolant to flow out from a position corresponding to the fin part 212.

According to this configuration, since the coolant A is directed in the guide direction E, the flow rate of the coolant A flowing therethrough increases even at a position away from the main line L in a direction intersecting the main line L, and the cooling performance at that position is enhanced. As a result, the temperature differences among the semiconductor devices 10 are reduced, and the temperature of the semiconductor device 10 that reaches the highest temperature is reduced. Furthermore, since the coolant A is guided in the guide direction E through the interior of the structure 240, the coolant A can be reliably guided in the guide direction E as compared with a configuration in which the coolant A flowing along the surface of the structure 240 is controlled by, for example, the shape of the surface of the structure 240.

In the cooler 20 of the present embodiment, the structure 240 includes a first facing surface 242M1 facing the inlet port 204A of the first wall portion 200M1. On the first facing surface 242M1, an intake hole 244 for taking in the coolant A that has flowed from the inlet port 204A is provided on an extension line of the inlet port 204A in the penetrating direction. According to this configuration, the coolant A flowing in from the inlet port 204A can be smoothly taken in from the intake hole 244. In addition, it is also possible to easily form the intake hole 244 by way of a tool inserted from the inlet port 204A.

In the cooler 20 of the present embodiment, the structure 240 includes a top surface 242M3 that faces the fin part 212 of the second main face 210S2 of the heat dissipation substrate 210. The top surface 242M3 is provided with at least one outflow hole 246, the opening of which has a shape that extends in the guide direction E intersecting the main line L in plan view. The outflow hole 246 allows the coolant A taken in from the intake hole 244 to flow out. According to this configuration, the coolant A can be reliably guided in the guide direction E crossing the main line L, and is allowed to flow out to a portion corresponding to the fin part 212.

In the cooler 20 of the present embodiment, the number of the semiconductor devices 10 is two or more, and the semiconductor devices 10 are mounted along the guide direction E. According to this configuration, the temperature differences among the semiconductor devices 10 caused by the unevenness in the cooling performance is reduced.

In the cooler 20 of the present embodiment, the number of the outflow holes 246 is two, and on the top surface 242M3, the two outflow holes 246 are provided on each side of the intake hole 244 to sandwich the intake hole 244 therebetween. According to this configuration, in the guide direction E intersecting the main line L, the cooling performance by the coolant A flowing along the first facing surface 242M1 and the cooling performance by the coolant A flowing out of the outflow holes 246 are balanced.

In the cooler 20 of the present embodiment, the outflow holes 246 are provided upstream of the flows of the coolant A on the top surface 242M3. According to this configuration, since the coolant A can flow in substantially the entire region directly below the semiconductor devices 10, the heat generated by the semiconductor devices 10 can be removed more efficiently, and the cooling performance can be improved.

### 2. Modifications

Modifications added to the above-described embodiment are exemplified below. Two or more forms freely selected from the following examples may be appropriately combined so long as they do not conflict with each other. In the drawings referred to in the following description, elements similar to those described in the embodiment are denoted by the same reference numerals.

### Modification 1

FIG. 14 is a diagram illustrating an example of a configuration of a case body 200 according to a first modification of the present disclosure. As illustrated in FIG. 14, in the structure 240 of the case body 200, the first facing surface 242M1 may be a surface substantially perpendicular to the bottom surface portion 200M5 instead of being an inclined surface. The first facing surface 242M1 may be an inclined surface inclined at an obtuse angle with respect to the bottom surface portion 200M5. The angle of inclination of the first facing surface 242M1 is appropriately set in accordance with the above-described pressure loss, unevenness in the cooling performance within the device mounting area C3, and the like.

Furthermore, as shown in FIG. 14, the second facing surface 242M2 of the structure 240 may be a surface substantially perpendicular to the bottom surface portion 200M5 instead of being an inclined surface. The second facing surface 242M2 may be an inclined surface inclined at an obtuse angle with respect to the bottom surface portion 200M5.

### Modification 2

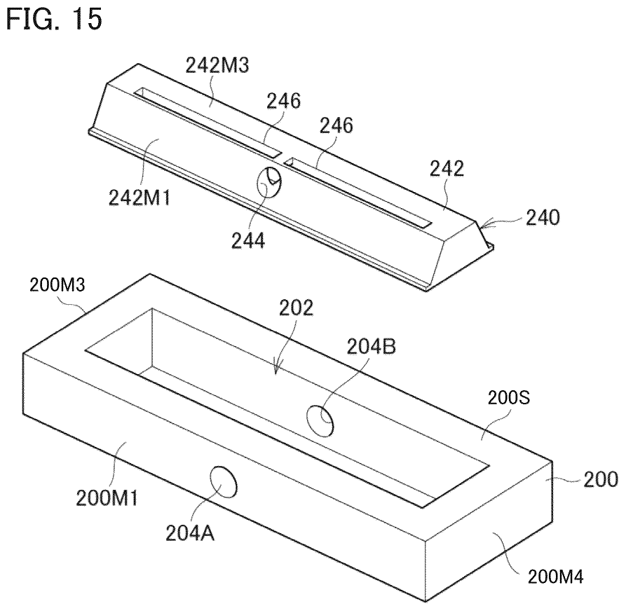

FIG. 15 is an exploded perspective view illustrating an example of a configuration of a case body 200 according to a second modification of the present disclosure. The structure 240 is not limited to a structure that is an integrally molded product with the case body 200, and may be separate from the case body 200 as shown in FIG. 15.

### Modification 3

In the above-described embodiment, the guide direction E in which the outflow hole 246 extends may be a direction intersecting the main line L, and may not necessarily coincide with the direction of the long axis K of the device mounting area C3 and the direction in which the semiconductor devices 10 are arranged. That is, the guide direction E may be a direction intersecting the main line L at an acute angle or an obtuse angle instead of being a direction orthogonal to the main line L.

### Modification 4

In the above-described embodiment, the main line L is located substantially at the center of the cooler 20 in the direction of the long axis K, and the outflow holes 246 are provided on each side of the main line L. However, in a case in which the main line L is located away from the substantially center in the direction of the long axis K in the cooler 20, the outflow holes 246 may be provided on one side of the main line L.

### Modification 5

In the above-described embodiment, the shape of the outflow hole 246 on the top surface 242M3 is a shape in which the width in the direction of the main line Lis constant at any point in the guide direction E. However, the width may not be constant. For example, as the distance from the main line L in the guide direction E increases, the width may increase or the width may decrease.

### Modification 6

In the above-described embodiment, the inlet port 204A of the case body 200 and the intake hole 244 of the structure 240 may be connected by a tube. The tube may comprise, for example, a distal end of the inlet tube 4A.

### Modification 7

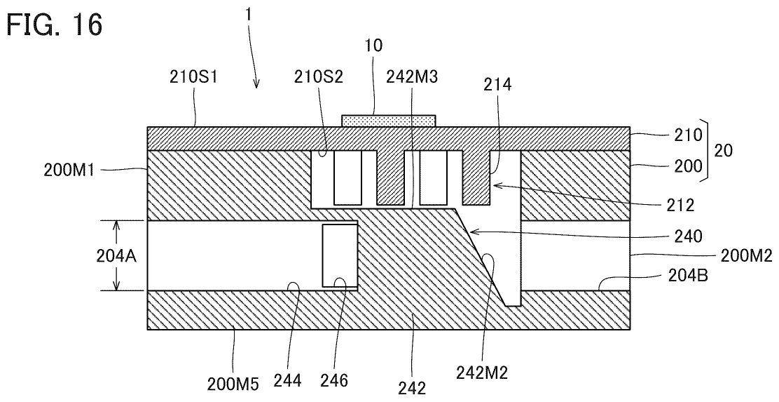

In the above-described embodiment, an example is given of a configuration in which the first facing surface 242M1 of the structure 240 (the main body portion 242) faces the inner wall surface of the first wall portion 200M1 with a space therebetween. However, as illustrated in FIG. 16, the first wall portion 200M1 and the structure 240 may be integrally formed. That is, the first facing surface 242M1 is not formed in the structure 240, and the top surface 242M3 is directly connected to the inner wall surface of the first wall portion 200M1. The intake hole 244 of the structure 240 is in direct communication with the inlet port 204A of the first wall 200M1.

In the above-described configuration, the coolant A introduced from the inlet port 204A is directly taken into the structure 240 from the intake hole 244, and the coolant A diffuses in the guide direction E inside the structure 240 and then flows out of the respective outflow holes 246. The coolant A flowing out of the structure 240 passes through the space between the top surface 242M3 and the heat dissipation substrate 210, and is discharged from the discharge port 204B of the second wall portion 200M2. Also in the configuration of FIG. 16, effects similar to those of the above-described embodiment can be realized.

### Modification 8

In the above-described embodiment, the inlet port 204A is installed on the first wall portion 200M1 and the discharge port 204B is installed on the second wall portion 200M2, but the locations of the inlet port 204A and the discharge port 204B are not limited to the above example.

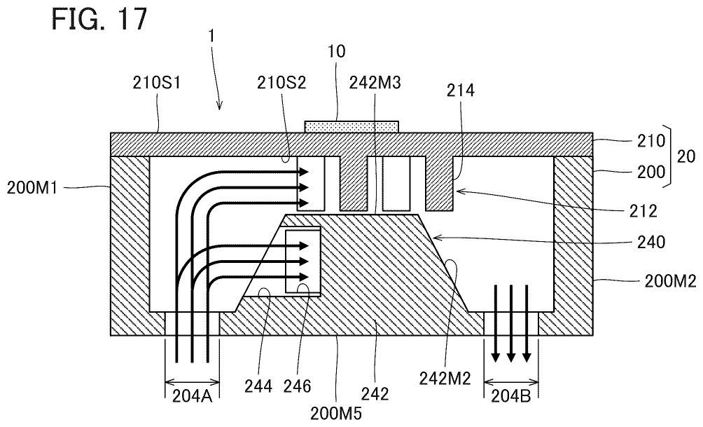

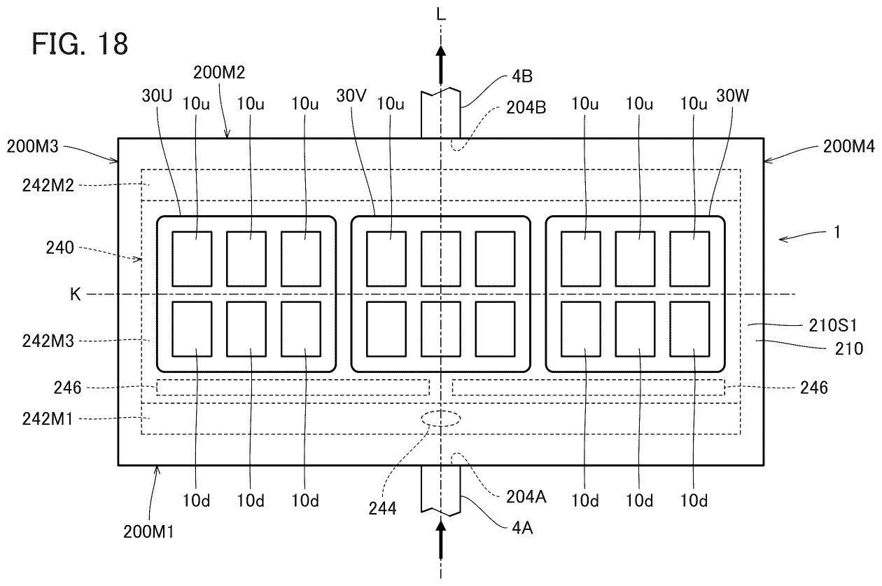

For example, as illustrated in FIG. 17, the inlet port 204A may be formed in the bottom surface portion 200M5, and specifically in a region that lies between the first wall portion 200M1 and the structure 240 when viewed in plan. The inlet tube 4A communicating with the inlet port 204A is connected to the bottom surface portion 200M5. A part of the coolant A that has passed through the inlet port 204A is taken into the intake hole 244 and flows out of the respective outflow holes 246. The other part of the coolant A that has passed through the inlet port 204A reaches the top surface 242M3 along the first facing surface 242M1.

Furthermore, as illustrated in FIG. 17, the discharge port 204B may be formed in the bottom surface portion 200M5, specifically in a region that lies between the second wall portion 200M2 and the structure 240 in plan view. The outlet tube 4B communicating with the discharge port 204B is connected to the bottom surface portion 200M5. The discharge port 204B is positioned in the direction of the main line L with respect to the inlet port 204A. That is, in both the above-described embodiment and the configuration of FIG. 17, the inlet port 204A and the discharge port 204B are located on the main line L in plan view.

As described above, the position where the inlet port 204A and the discharge port 204B are formed may be freely selected. However, according to the configuration in which the inlet port 204A is formed on the first wall portion 200M1 as in the above-described embodiment, the intake hole 244 can be installed at a position opposite to the inlet port 204A. Therefore, there is an advantage in that the coolant A introduced from the inlet port 204A can be efficiently supplied to the intake hole 244. It is to be noted that, in the configuration of FIG. 16 in which the first wall portion 200M1 and the structure 240 are continuous, the inlet port 204A and the discharge port 204B may be formed on the bottom surface portion 200M5 in the same manner as in FIG. 17.

### Modification 9

In the above-described embodiment, an example is given of the configuration in which the plurality of semiconductor devices 10 is mounted on the cooler 20, but a configuration in which the respective semiconductor devices 10 are mounted on the cooler 20 is not limited to the above-described example. For example, as illustrated in FIG. 18, semiconductor modules 30 (30U,30V,30W) each including a plurality of semiconductor devices 10 may be mounted on the cooler 20.

FIG. 18 illustrates a configuration in which three semiconductor modules 30 (30U,30V,30W) are mounted on the first main face 210S1 of the heat dissipation substrate 210. Specifically, the three semiconductor modules 30 are arranged at a distance from each other along the long axis K.

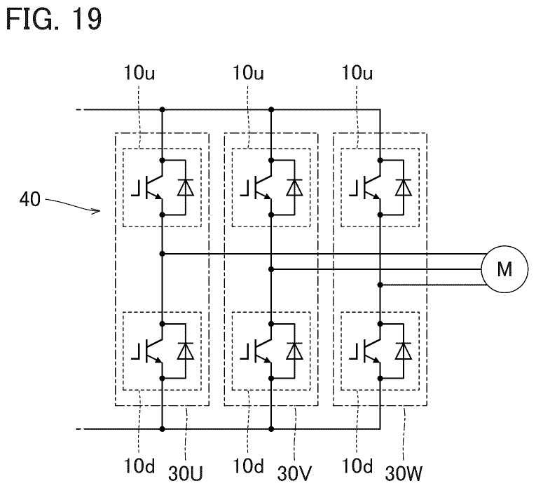

The three semiconductor modules 30 constitute, for example, a power conversion device 40 as illustrated in FIG. 19. The power conversion device 40 in FIG. 19 is a three-phase inverter circuit that converts DC power into AC power. The semiconductor module 30U corresponds to the U phase, the semiconductor module 30V corresponds to the V phase, and the semiconductor module 30W corresponds to the W phase. The power conversion device 40 is not limited to an inverter circuit. For example, the power conversion device 40 such as a converter circuit or a chopper circuit may be constituted by the semiconductor module 30.

As illustrated in FIG. 18, each semiconductor module 30 includes three upper arm elements 10u and three lower arm elements 10d. As illustrated in FIG. 19, each upper arm element 10u is a semiconductor device including, for example, a switching device and a diode. Three upper arm elements 10u, an example of which is shown in FIG. 19, are arranged in parallel, as illustrated in FIG. 18. Likewise, each lower arm element 10d is a semiconductor device including, for example, a switching device and a diode. Three lower arm elements 10d, an example of which is shown in FIG. 19, are arranged in parallel, as illustrated in FIG. 18. As shown in FIG. 18, the three upper arm elements 10u in the respective semiconductor module 30 are disposed in one of two regions that lies sandwiching the long axis K, and the three lower arm elements 10d are disposed in the other region.

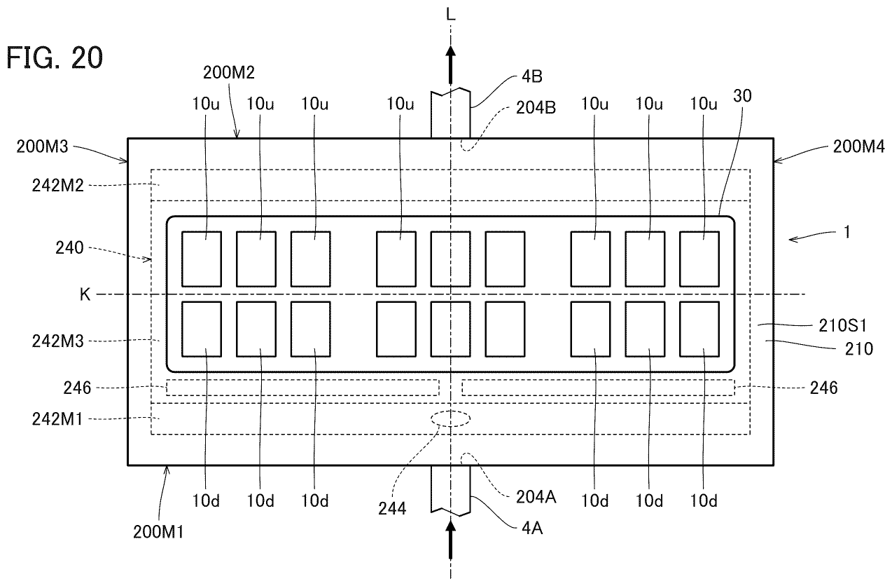

As described above, also in the configuration of FIG. 18, a plurality of semiconductor devices (the upper arm elements 10u and the lower arm elements 10d) is mounted on the cooler 20. Although three semiconductor modules 30 are illustrated in FIG. 18, as illustrated in FIG. 20, a single semiconductor module 30 constituting the power conversion device 40 illustrated in FIG. 19 may be mounted on the cooler 20.

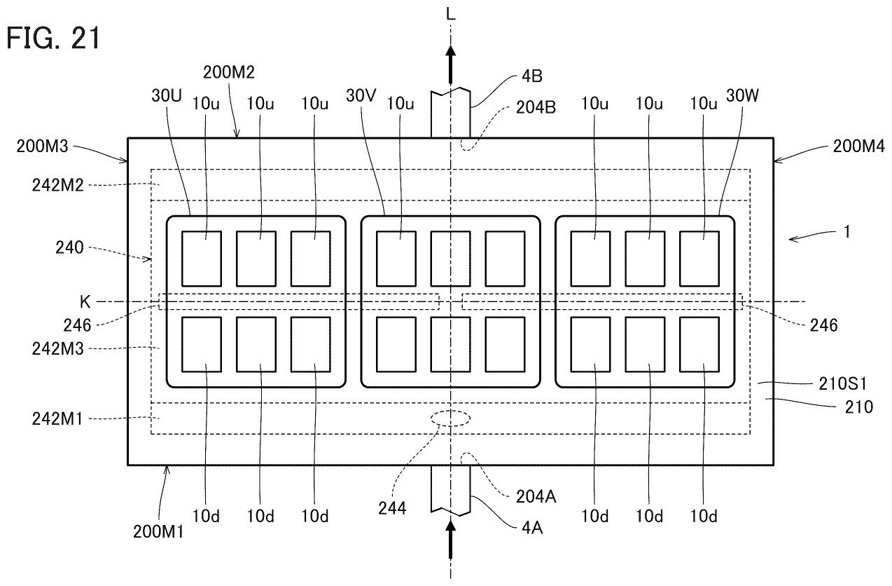

FIG. 18 illustrates a configuration in which the pair of outflow holes 246 is positioned between the row of the plurality of semiconductor modules 30 and the first wall portion 200M1 of the case body 200 in plan view. However, the positional relation between the plurality of semiconductor modules 30 and the pair of outflow holes 246 is not limited to the above example. For example, as illustrated in FIG. 21, a pair of outflow holes 246 may be formed between the row of the plurality of upper arm elements 10u and the row of the plurality of lower arm elements 10d. In the configuration of FIG. 21, the plurality of lower arm elements 10d is cooled by the coolant A that has reached the top surface 242M3 along the first facing surface 242M1 of the structure 240. On the other hand, the plurality of upper arm elements 10u is cooled by the coolant A that has reached the top surface 242M3 from the first facing surface 242M1 and the coolant A that has flowed out from the interior of the structure 240 to the top surface 242M3 through the respective outflow holes 246.

The semiconductor module 30 (30U,30V,30W), the upper arm element 10u, the lower arm element 10d, and the semiconductor device 10 are each an example of a “semiconductor device” according to this disclosure.

### Modification 10

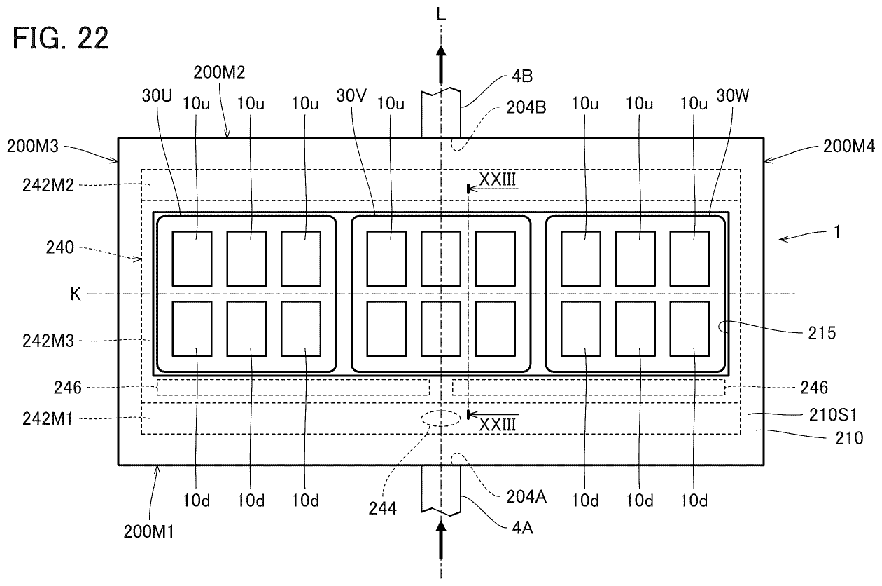

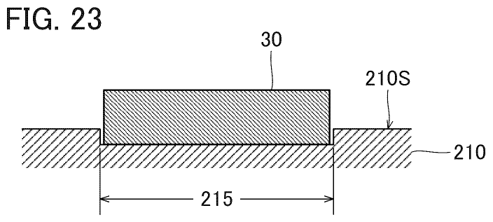

As illustrated in FIG. 22, a recess 215 may be formed on the first main face 210S1 of the heat dissipation substrate 210. FIG. 23 is a cross-sectional view, taken along line XXIII-XXIII in FIG. 22. As illustrated in FIGS. 22 and 23, the recess 215 on the first main face 210S1 is a rectangular recess having a slightly larger outer dimension than the row of the three semiconductor modules 30. The three semiconductor modules 30 are mounted on the cooler 20 in a state of being accommodated in the recess 215. The depth of the recess 215 is less than the height of the semiconductor module 30.

According to the configuration of FIG. 22, with the side surface of each semiconductor module 30 and the inner wall surface of the recess 215 contacting each other, each semiconductor module 30 is positioned in a plane parallel to the first main face 210S1.

### Modification 11

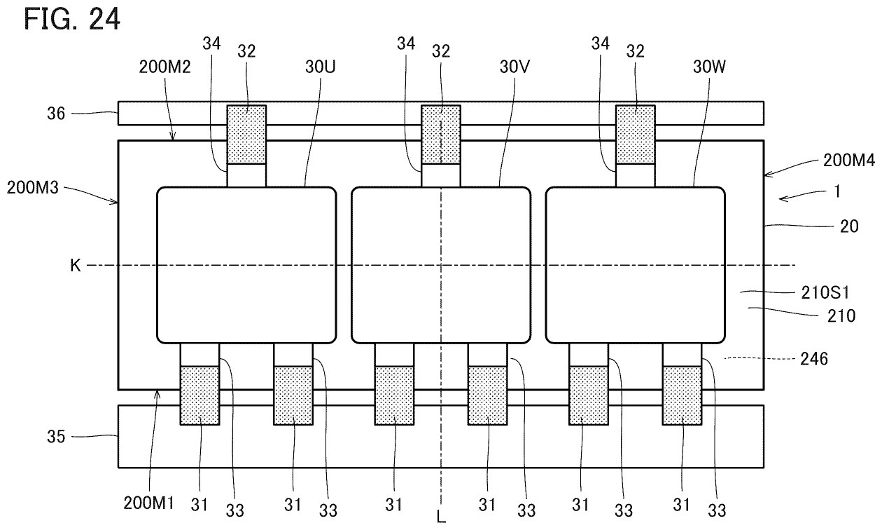

In the above-described embodiment, the semiconductor device 10 is joined to the first main face 210S1 of the heat dissipation substrate 210, but the configuration for mounting the semiconductor device 10 on the heat dissipation substrate 210 is not limited to the above example. For example, a plurality of semiconductor modules 30 may be mounted on the cooler 20 by a configuration illustrated in FIG. 24.

The semiconductor apparatus 1 of FIG. 24 includes a plurality of connection conductors 31, a plurality of output conductors 32, a capacitor 35, and a holding member 36 in addition to the plurality of semiconductor modules 30 (30U,30V,30W) and the cooler 20. Two connection conductors 31 and one output conductor 32 are provided for each of the plurality of semiconductor modules 30.

The capacitor 35 is a passive component used for, for example, smoothing of a voltage in the power conversion device 40, and is fixed to a housing (not shown). Each connection conductor 31 is a conductor for electrically connecting the semiconductor apparatus 1 and the capacitor 35. The connection conductor 31 is, for example, a bus bar.

Each output conductor 32 is a conductor for electrically connecting the semiconductor apparatus 1 and an external device (not shown) such as an electric motor. The output conductor 32 is, for example, a bus bar. The holding member 36 is a structure for supporting and fixing the plurality of output conductors 32 to the housing (not shown). The cooler 20 is located between the capacitor 35 and the plurality of output conductors 32 in plan view.

Each semiconductor module 30 includes two connection terminals 33 and one output terminal 34. Each of the connection terminals 33 is electrically connected to the capacitor 35 by being joined to the connection conductor 31. The output terminal 34 is electrically connected to an external device such as an electric motor by being joined to the output conductor 32.

Each semiconductor module 30 is supported between the capacitor 35 and the holding member 36 by joining of the connection terminals 33 to the respective connection conductors 31 and joining of the output terminals 34 to the respective output conductors 32. Specifically, the respective semiconductor modules 30 are supported between the capacitor 35 and the holding member 36 with the bottom surface contacting the first main face 210S1 of the heat dissipation substrate 210.

As illustrated above, in the configuration of FIG. 24, each semiconductor module 30 (semiconductor device) is supported by a support member such as the capacitor 35 or the holding member 36, thereby being positioned in a plane parallel to the first main face 210S1, and the semiconductor module 30 is mounted on the cooler 20. Therefore, the semiconductor module 30 need not be directly joined to the first main face 210S1. In the configuration of FIG. 24, the semiconductor modules 30 may be joined to the first main face 210S1 by a joining material primarily including a high thermal conductivity material.

### Modification 12

In the above-described embodiment, in the case body 200 having a rectangular shape in plan view, the first wall portion 200M1 and the second wall portion 200M2 each comprise a long side of a rectangle, and the third wall portion 200M3 and the fourth wall portion 200M4 each comprise a short side of the rectangle, but the shape of the case body 200 is not limited to the above example.

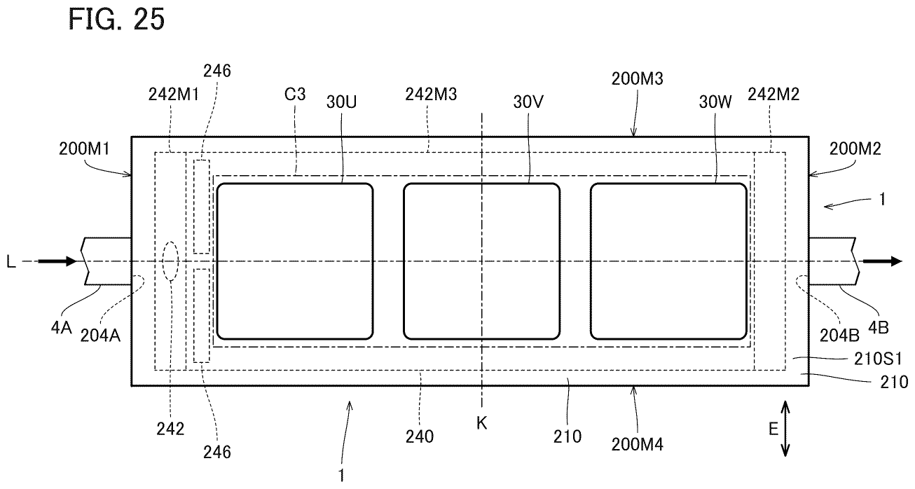

For example, as illustrated in FIG. 25, the first wall portion 200M1 and the second wall portion 200M2 may each comprise a short side of the rectangle, and the third wall portion 200M3 and the fourth wall portion 200M4 may each comprise a long side of the rectangle. The inlet port 204A is disposed on the first wall portion 200M1, and the discharge port 204B is disposed on the second wall portion 200M2. Accordingly, the coolant A flowing into the case body 200 from the inlet port 204A flows along the longitudinal direction of the case body 200. The guide direction E corresponds to the lateral direction of the case body 200.

The semiconductor modules 30 (30U,30V,30W) mounted on the first main face 210S1 of the heat dissipation substrate 210 are spaced apart from each other along the longitudinal direction of the case body 200. In the configuration of FIG. 25, the pair of outflow holes 246 is formed between the semiconductor module 30U and the first wall portion 200M1 in plan view. Therefore, the plurality of semiconductor modules 30 is cooled by the coolant A that has passed through the outflow holes 246 from the interior of the structure 240 and reached the top surface 242M3.

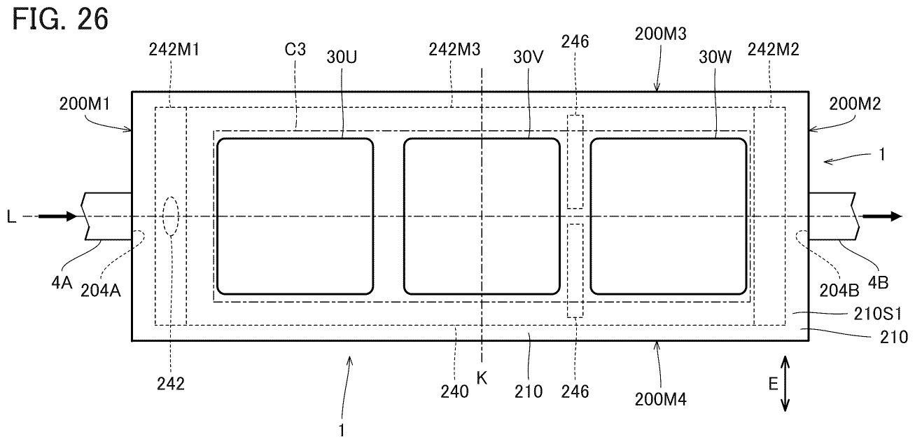

Although FIG. 25 illustrates a configuration in which the pair of outflow holes 246 is formed upstream of the semiconductor module 30U, the locations of the pair of outflow holes 246 are not limited to the above examples. For example, as illustrated in FIG. 26, the pair of outflow holes 246 may be formed between the semiconductor module 30V and the semiconductor module 30W in plan view. The pair of outflow holes 246 may be formed between the semiconductor module 30U and the semiconductor module 30V in plan view.

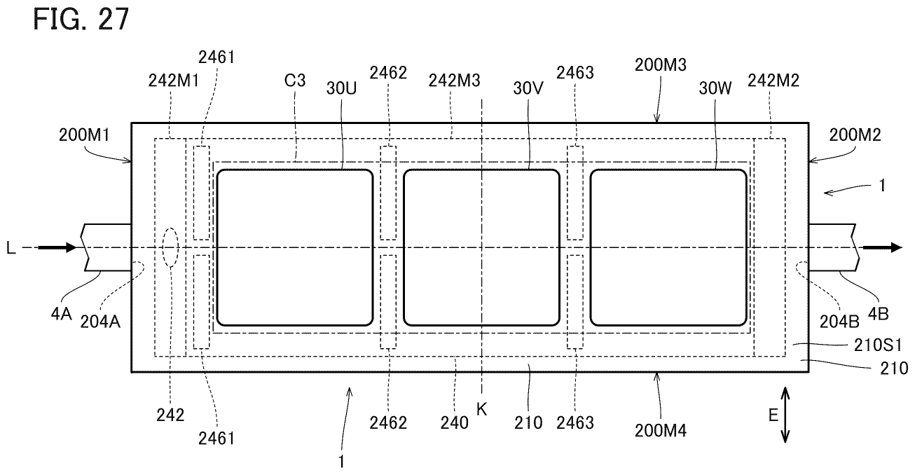

As illustrated in FIG. 27, a plurality of pairs of outflow holes 246 (2461,2462,2463) may be formed in the structure 240. Specifically, a pair of outflow holes 246 may be individually formed for each semiconductor module 30. In the configuration of FIG. 27, a plurality of pairs of outflow holes 246 is formed at intervals along the direction in which the plurality of semiconductor modules 30 is arranged.

Specifically, the pair of outflow holes 2461 is located between the semiconductor module 30U and the first wall portion 200M1 in plan view. The pair of outflow holes 2462 is located between the semiconductor module 30U and the semiconductor module 30V in plan view. The pair of outflow holes 2463 is located between the semiconductor module 30V and the semiconductor module 30W in plan view.

In the above-described configuration, the semiconductor module 30U is cooled by the coolant A flowing out of the outflow holes 2461. The semiconductor module 30V is cooled by the coolant A flowing out of the outflow holes 2461 and the outflow holes 2462. The semiconductor module 30W is cooled by the coolant A flowing out of the outflow holes 2461, the outflow holes 2462, and the outflow holes 2463.

The shape or size of the outflow holes 2461, the outflow holes 2462, and the outflow holes 2463 may be the same as or be different from each other. For example, the opening area (for example, the width of the outflow hole 246) of the outflow holes 246 located on the downstream side of the coolant A may be larger. Specifically, each of the outflow holes 2462 has a larger area than the outflow holes 2461, and each of the outflow holes 2463 has a larger area than the outflow holes 2462. According to the above configuration, the flow rate of the coolant A is readily secured also for the outflow holes 246 located further downstream.

### DESCRIPTION OF REFERENCE SIGNS

1 . . . semiconductor apparatus, 4A . . . inlet tube, 4B . . . outlet tube, 10 . . . semiconductor device, 20 . . . cooler, 200 . . . case body, 200M1 . . . first wall portion, 200M2 . . . second wall portion, 200M3 . . . third wall portion, 200M4 . . . fourth wall portion, 200M5 . . . bottom surface, 200S . . . sealing surface, 202 . . . opening, 204A . . . inlet port, 204B . . . discharge port, 210 . . . heat dissipating board, 210S1 . . . first main face, 210S2 . . . second main face, 212 . . . fin part, 214 . . . fin, 240 . . . structure, 242 . . . body part, 242M1 . . . first facing surface, 242M3 . . . top surface, 244 . . . intake hole, 246 . . . outflow hole, A . . . coolant, C3 . . . device mounting range, D . . . up-and-down direction, Dd . . . downward direction, Du . . . upward direction, E . . . guide direction, K . . . long axis, L . . . main line.

What is claimed is:

1. A cooler comprising:
a heat dissipation substrate including a first main face on which one or more semiconductor devices are mounted and a second main face with a fin part;
a case body that is in close contact with the second main face and configured to accommodate the fin part; and
a structure,
wherein the case body includes:
a first wall portion,
a second wall portion facing the first wall portion,
an inlet port for introducing coolant into an interior of the case body, and
a discharge port for discharging the coolant from the interior of the case body, the discharge port being positioned relative to the inlet port in a direction of a main line extending from the first wall portion to the second wall portion, and
wherein the structure is configured to intake the coolant flowing in from the inlet port into the interior, and directs the coolant in a guide direction intersecting the main line, to allow the coolant to flow out from a position that corresponds to the fin part.

2. The cooler according to claim 1,
wherein the inlet port is provided in the first wall portion, and
wherein the discharge port is provided in the second wall portion.

3. The cooler according to claim 2,
wherein the structure includes a first facing surface facing the first wall portion, and
wherein the first facing surface includes an intake hole to intake the coolant flowing in from the inlet port into the interior, the intake hole being provided on an extension line of a direction in which the inlet port passes through.

4. The cooler according to claim 3,
wherein the structure includes a top surface facing the second main face, and
wherein the top surface includes one or more outflow holes for allowing the coolant taken in from the intake hole to flow out, each of the one or more outflow holes having a shape that extends in the guide direction in plan view.

5. The cooler according to claim 4,
wherein the one or more semiconductor devices comprise two or more semiconductor devices, and
wherein the two or more semiconductor devices are mounted along the guide direction.

6. The cooler according to claim 4,
wherein the one or more outflow holes comprise two outflow holes,
wherein the main line is a line linearly connecting the inlet port and the discharge port, and
wherein the top surface includes the two outflow holes on each side of the main line.

7. The cooler according to claim 4, wherein the one or more outflow holes are provided upstream of a flow of the coolant on the top surface.

8. A semiconductor apparatus comprising:
one or more semiconductor devices;
a cooler for cooling the one or more semiconductor devices,
wherein the cooler includes:
a heat dissipation substrate including a first main face on which the one or more semiconductor devices are mounted and a second main face with a fin part;
a case body that is in close contact with the second main face and configured to accommodate the fin part; and
a structure,
wherein the case body includes:
a first wall portion,
a second wall portion facing the first wall portion,
an inlet port for introducing coolant into an interior of the case body, and
a discharge port configured to discharge the coolant from the interior of the case body, the discharge port being positioned relative to the inlet port in a direction of a main line extending from the first wall portion to the second wall portion, and
wherein the structure is configured to intake the coolant flowing in from the inlet port into the interior, and directs the coolant in a guide direction intersecting the main line, to cause the coolant to flow out from a position that corresponds to the fin part.
